(19) United States
(12) Patent Application Publication
(10) Pub. No.: US 2018/0114768 A1
(43) Pub. Date: Apr. 26, 2018

(54) SEMICONDUCTOR CHIP, ELECTRONIC DEVICE HAVING THE SAME AND METHOD OF CONNECTING SEMICONDUCTOR CHIP TO ELECTRONIC DEVICE

(71) Applicant: Samsung Display Co., Ltd., Yongin-si (KR)

(72) Inventors: Sang Hyeon SONG, Yongin-si (KR); Seung Hwa HA, Yongin-si (KR); Byoung Yong KIM, Yongin-si (KR); Jeong Ho HWANG, Yongin-si (KR)

(21) Appl. No.: 15/787,609

(22) Filed: Oct. 18, 2017

(30) Foreign Application Priority Data
Oct. 20, 2016 (KR) 10-2016-0136379

(51) Int. Cl. H01L 23/00; H01L 23/29; H01L 23/31

(52) U.S. Cl. CPC H01L 24/81; H01L 23/293; H01L 23/3171; H01L 2224/81007; H01L 2224/81193; H01L 2224/8183; H01L 23/296; H01L 2224/81206

(57) ABSTRACT

Provided herein may be an electronic device. The electronic device may include a substrate provided with a plurality of connecting pads including a first metal, a semiconductor chip on an area of the substrate, facing the connecting pads, and including a base substrate including a first surface facing the substrate, and a second surface opposite the first surface, a plurality of connecting terminals on the first surface, facing the connecting pads, and including a second metal, and a non-adhesive polymer layer on the second surface, and a conductive joining layer electrically connecting, and interposed between, respective ones of the connecting pads to the connecting terminals, and including a diffusion layer in which the first metal and the second metal are mixed.

### CROSS-REFERENCE TO RELATED APPLICATION

This application claims priority to, and the benefit of, Korean patent application number 10-2016-0136379 filed on Oct. 20, 2016, the entire disclosure of which is incorporated herein in its entirety by reference.

### BACKGROUND

### 1. Field

Various embodiments of the present disclosure relate to a semiconductor chip, an electronic device having the same, and a method of connecting the semiconductor chip to the electronic device.

### 2. Description of Related Art

Generally, a semiconductor chip includes a plurality of connecting terminals to connect an internal circuit element to a substrate or to a circuit element of an electronic device. An adhesive, such as an anisotropic conductive film (hereinafter, referred to simply as “ACF”), may be used to connect the semiconductor chip to the electronic device.

However, following the recent trend of high performance and high integration of the electronic device, a size of respective connecting terminals, and also a pitch between adjacent connecting terminals, are rapidly reduced, and a defect may occur when connecting the semiconductor chip to the electronic device using the ACF.

### SUMMARY

Various embodiments of the present disclosure are directed to a semiconductor chip, an electronic device having the same, and a method of connecting the semiconductor chip to the electronic device that is capable of stably and directly connecting the semiconductor chip to the electronic device.

An embodiment of the present disclosure provides an electronic device including a substrate provided with a plurality of connecting pads including a first metal, a semiconductor chip on an area of the substrate, facing the connecting pads, and including a base substrate including a first surface facing the substrate, and a second surface opposite the first surface, a plurality of connecting terminals on the first surface, facing the connecting pads, and including a second metal, and a non-adhesive polymer layer on the second surface, and a conductive joining layer electrically connecting, and interposed between, respective ones of the connecting pads to the connecting terminals, and including a diffusion layer in which the first metal and the second metal are mixed.

The polymer layer may include at least one of silicon sealant, photocurable resin, polydimethylsiloxane and polyurethane.

The polymer layer may include insulating material that is softer than material of the base substrate.

The electronic device may be provided with a display panel including the substrate.

The polymer layer may include at least one of a material that forms a sealant sealing a display area of the display panel, and a material that forms a sealing agent located on a perimeter of the display panel.

The substrate may include a flexible thin-film substrate.

The polymer layer may include a material of the substrate.

The polymer layer may have a thickness ranging from about 30 μm to about 40 μm.

The first metal and the second metal may include an identical kind of metal or different kinds of metals.

An embodiment of the present disclosure provides a semiconductor chip including a base substrate, a plurality of connecting terminals on a first surface of the base substrate, and a non-adhesive polymer layer located on a second surface of the base substrate opposite the first surface.

The polymer layer may include at least one of silicon sealant, photocurable resin, polydimethylsiloxane and polyurethane.

The polymer layer may have a thickness ranging from about 30 μm to about 40 μm.

An embodiment of the present disclosure provides a method of connecting a semiconductor chip to an electronic device includes preparing a substrate including a plurality of connecting pads, preparing a semiconductor chip including a plurality of connecting terminals, and a non-adhesive polymer layer, on respective surfaces facing away from each other, aligning the semiconductor chip on the substrate such that the connecting pads and the connecting terminals face each other, disposing a vibration device on the semiconductor chip, the vibration device including a plurality of protrusions, joining the connecting pads with the connecting terminals by pressing the semiconductor chip using the vibration device such that the protrusions are embedded into the polymer layer, and vibrating the semiconductor chip, and removing the vibration device from the semiconductor chip.

The joining of the connecting pads with the connecting terminals may include forming a conductive joining layer between the connecting pads and the connecting terminals, the conductive joining layer including a mixture of a first metal of the connecting pads and a second metal of the connecting terminals.

The first metal and the second metal may include an identical kind of metal or different kinds of metals.

The joining of the connecting pads with the connecting terminals may include applying vibration having a frequency in an ultrasonic range to the semiconductor chip to vibrate the semiconductor chip in a horizontal direction that is perpendicular to a direction in which a load is applied to the semiconductor chip.

The polymer layer may have a thickness that is greater than a height of the protrusions.

### BRIEF DESCRIPTION OF THE DRAWINGS

Example embodiments will now be described more fully hereinafter with reference to the accompanying drawings, in which:

FIGS. 1A and 1B are perspective views illustrating a semiconductor chip according to an embodiment of the present disclosure;

FIG. 2 is a perspective view illustrating an electronic device according to an embodiment of the present disclosure;

FIG. 3 is a sectional view schematically illustrating an example of a cross section taken along the line I-I′ of FIG. 2;

FIG. 4 is a sectional view schematically illustrating another example of a cross section taken along the line I-I′ of FIG. 2; and

FIGS. 5A to 5E are sectional views illustrating a method of connecting a semiconductor chip to an electronic device according to an embodiment of the present disclosure.

### DETAILED DESCRIPTION

Features of the inventive concept and methods of accomplishing the same may be understood more readily by reference to the following detailed description of embodiments and the accompanying drawings. Hereinafter, embodiments will be described in more detail with reference to the accompanying drawings, in which like reference numbers refer to like elements throughout. The present invention, however, may be embodied in various different forms, and should not be construed as being limited to only the illustrated embodiments herein. Rather, these embodiments are provided as examples so that this disclosure will be thorough and complete, and will fully convey the aspects and features of the present invention to those skilled in the art. Accordingly, processes, elements, and techniques that are not necessary to those having ordinary skill in the art for a complete understanding of the aspects and features of the present invention may not be described. Unless otherwise noted, like reference numerals denote like elements throughout the attached drawings and the written description, and thus, descriptions thereof will not be repeated. In the drawings, the relative sizes of elements, layers, and regions may be exaggerated for clarity.

In the following description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present invention.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when an element, layer, region, or component is referred to as being “on,” “connected to,” or “coupled to” another element, layer, region, or component, it can be directly on, connected to, or coupled to the other element, layer, region, or component, or one or more intervening elements, layers, regions, or components may be present. However, “directly connected/directly coupled” refers to one component directly connecting or coupling another component without an intermediate component. In addition, it will also be understood that when an element or layer is referred to as being “between” two elements or layers, it can be the only element or layer between the two elements or layers, or one or more intervening elements or layers may also be present.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

In the following examples, the x-axis, the y-axis and the z-axis are not limited to three axes of a rectangular coordinate system, and may be interpreted in a broader sense. For example, the x-axis, the y-axis, and the z-axis may be perpendicular to one another, or may represent different directions that are not perpendicular to one another.

The terminology used herein is for the purpose of describing particular embodiments only and is not intended to be limiting of the present invention. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively. Also, the term “exemplary” is intended to refer to an example or illustration.

When a certain embodiment may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

The electronic or electric devices and/or any other relevant devices or components according to embodiments of the present invention described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the exemplary embodiments of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

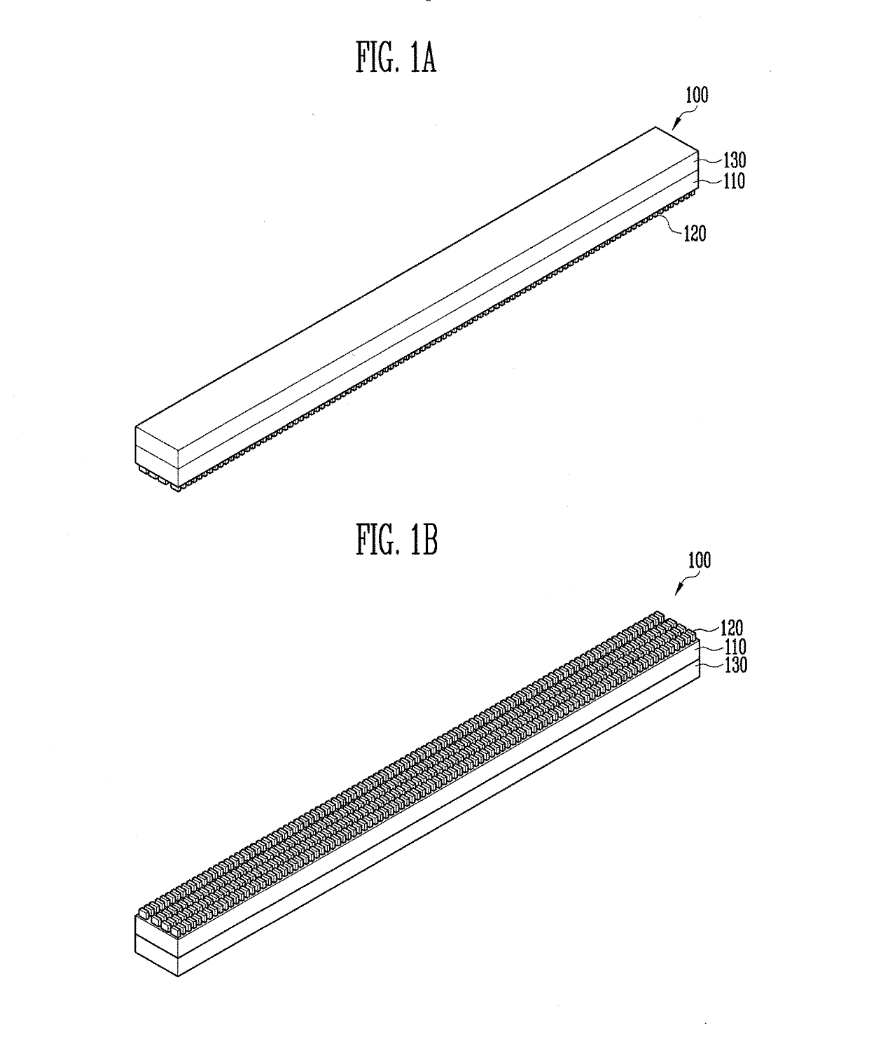

FIGS. 1A and 1B are perspective views illustrating a semiconductor chip according to an embodiment of the present disclosure.

Referring to FIGS. 1A and 1B, a semiconductor chip 100 according to an embodiment of the present disclosure includes a base substrate 110, which forms a body, a plurality of connecting terminals 120, which are located on a first surface of the base substrate 110, and a polymer layer 130, which is located on a second surface of the base substrate 110. The first surface and the second surface of the base substrate 110 may be surfaces facing away from each other. For example, when the semiconductor chip 100 is mounted on a substrate of an electronic device, the first surface of the semiconductor chip 100 may be a lower surface facing the substrate, and the second surface thereof may be an upper surface. For instance, the polymer layer 130 may be an uppermost layer that is located on an outer surface of the semiconductor chip 100.

The base substrate 110 may be a silicon wafer. However, the base substrate 110 is not limited to this, and the material and the shape of the base substrate 110 may vary. Furthermore, the base substrate 110 may be a rigid substrate or a flexible substrate. The base substrate 110 may include circuit layers in which various circuit elements and/or lines are located.

The plurality of connecting terminals 120 may be provided on one surface of the base substrate 110 (e.g., the first surface). The connecting terminals 120 may be configured to electrically connect (or couple) the circuit elements and/or the lines included in the base substrate 110 to an electronic device (e.g., a display panel). The connecting terminals 120 may be bump-type input/output pins, however, they are not limited thereto.

The plurality of connecting terminals 120 may be arranged in at least one row on the first surface of the base substrate 110. For example, at least one row of input connecting terminals and at least one row of output connecting terminals may be provided on the first surface of the base substrate 110. The input connecting terminals and the output connecting terminals may be arranged at positions spaced apart from each other (e.g., spaced by a predetermined distance or more).

Although FIGS. 1A and 1B illustrate an example in which the connecting terminals 120 are regularly arranged on the first surface of the semiconductor chip 100 in a lateral direction and in a longitudinal direction, the present disclosure is not limited to this. For example, the size (e.g., the length, the width, and the height) and the shape of each connecting terminal 120, the number of connecting terminals 120, the arrangement structure of the connecting terminals 120, and/or the pitch between adjacent connecting terminals 120 may vary. For, example, the connecting terminals 120 may be arranged in a zigzag manner in another embodiment.

The connecting terminals 120 may be formed of conductors. For instance, the connecting terminals 120 may be metal terminals including at least one kind of metal. Although examples of the metal which form the connecting terminals 120 may include copper (Cu), silver (Ag), gold (Au), platinum (Pt), palladium (Pd), nickel (Ni), tin (Sn), aluminum (Al), cobalt (Co), rhodium (Rh), iridium (Ir), iron (Fe), ruthenium (Ru), osmium (Os), manganese (Mn), molybdenum (Mo), tungsten (W), niobium (Nb), tantalum (Ta), titanium (Ti), bismuth (Bi), antimony (Sb), lead (Pb), etc., the connecting terminals 120 are not limited to the above. The connecting terminals 120 may be made of a single metal or an alloy. In addition, other materials as well as the above-described metals may be used to form the connecting terminals 120, so long as it can provide conductivity to the connecting terminals 120. The connecting terminals 120 may have a single-layer or multi-layer structure, and the structure thereof is not particularly limited.

According to an embodiment, although the polymer layer 130 may be formed of soft insulating material that is more flexible than that of the base substrate 110, the polymer layer 130 is not limited to this. For example, the polymer layer 130 may have enough flexibility to allow protrusions provided on a surface of a vibration head to be easily embedded thereinto, the vibration head being used in a joining (or connecting) process of the semiconductor chip 100 (or, a bonding process of the semiconductor chip 100), which will be described later herein. Although the polymer layer 130 may be formed of elastic material (e.g., polydimethylsiloxane (hereinafter, referred to simply as PDMS), or polyurethane, which have elasticity and restoring force, and which are capable of absorbing shock), the polymer layer 130 is not limited to this.

In addition, the polymer layer 130 may be formed of material that is softer than that of the protrusions, and may have a thickness that is greater than a height of the protrusions so that the protrusions of the vibration head are reliably received in the polymer layer 130 during the joining process. For example, the polymer layer 130 may have a thickness that is greater than the height of the protrusions by 10 μm or more. In an embodiment, when the height of the protrusions is 20 μm, the polymer layer 130 may have a thickness ranging from 30 μm to 40 μm. In this case, during the joining process, the base substrate 110 may be prevented from being damaged by the protrusions, and the vibration head may be prevented from slipping on the base substrate 110.

The polymer layer 130 may be made of material that is capable of preventing a slip, and that has excellent grip force, so that, during the joining process, the semiconductor chip 100 can come into close contact with the vibration head and can integrally vibrate with the vibration head. That is, because the polymer layer 130 is formed on the surface of the semiconductor chip 100, the grip force between the vibration head and the semiconductor chip 100 may be enhanced during the joining process.

Taking into account efficiency of the process, the polymer layer 130 must be easily separated from the vibration head after the joining process has been completed. Therefore, the polymer layer 130 may be embodied by a non-adhesive polymer layer having a comparatively low viscosity.

According to an embodiment, the polymer layer 130 may be directly applied on the base substrate 110. In this case, because a process of adhering a separate polymer sheet to the base substrate 110 may be omitted, the efficiency of the process may be enhanced. In addition, the polymer layer 130 is integrally formed with the semiconductor chip 100 on the base substrate 110 of the semiconductor chip 100. Thus, during the joining process, the polymer layer 130 may be prevented from separating from the base substrate 110. Therefore, during the joining process, the grip force between the vibration head and the semiconductor chip 100 is enhanced by the polymer layer 130, whereby the semiconductor chip 100 and the vibration head may integrally vibrate.

According to the present embodiment, displacement loss that may otherwise be caused during the joining process may be reduced, and vibration energy that is generated by the vibration head may be effectively transmitted to the semiconductor chip 100. Consequently, a conductive joining layer may be easily formed between the connecting terminals 120 and the connecting pads of the electronic device, and the quality of the joining therebetween may be improved. As a result, the connecting terminals 120 of the semiconductor chip 100 and the connecting pads of the electronic device may be stably and directly joined with, or connected to, each other, and low-resistance characteristics may be ensured between the connecting terminals 120 and the connecting pads.

Examples of material capable of satisfying characteristics required for the polymer layer 130 according to an embodiment of the present disclosure may include silicon sealant, photocurable resin (e.g., UV resin), PDMS, polyurethane, or the like. That is, the polymer layer 130 may include at least one of silicon sealant, photocurable resin, PDMS, and polyurethane. However, the material of the polymer layer 130 is not limited to this, and the polymer layer 130 may be formed of other material that is capable of satisfying characteristics required to facilitate the joining process.

The semiconductor chip 100 according to an embodiment of the present disclosure having the above-mentioned configuration may be stably and directly joined to, or connected to, the connecting pads of the electronic device, such as a display panel, without using an adhesive such as an ACF that contains conductive particles. Therefore, although the connecting terminals 120 have a fine size (e.g., have a fine width, length, and/or height), or although the pitch between adjacent connecting terminals 120 is fine (e.g., within a range from about 10 μm to about 15 μm or less), the connecting terminals 120 and the corresponding connecting pads may be stably coupled with each other. In addition, low-resistance characteristics may be ensured between the connecting terminals 120 and the connecting pads by the direct joining structure.

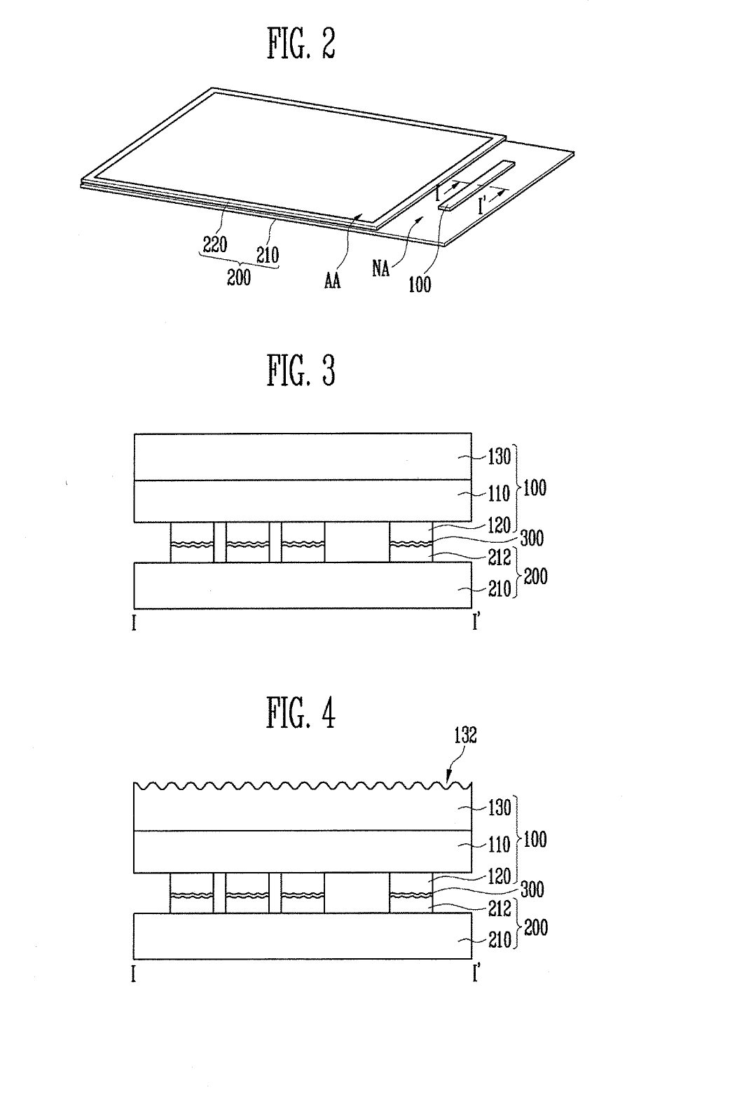

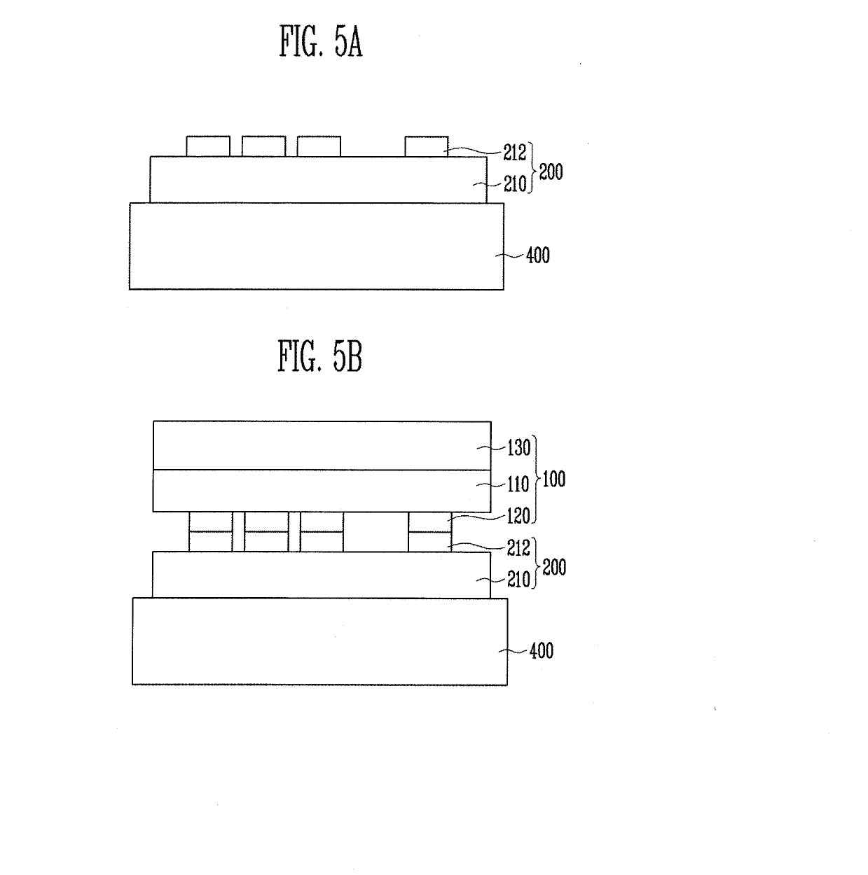

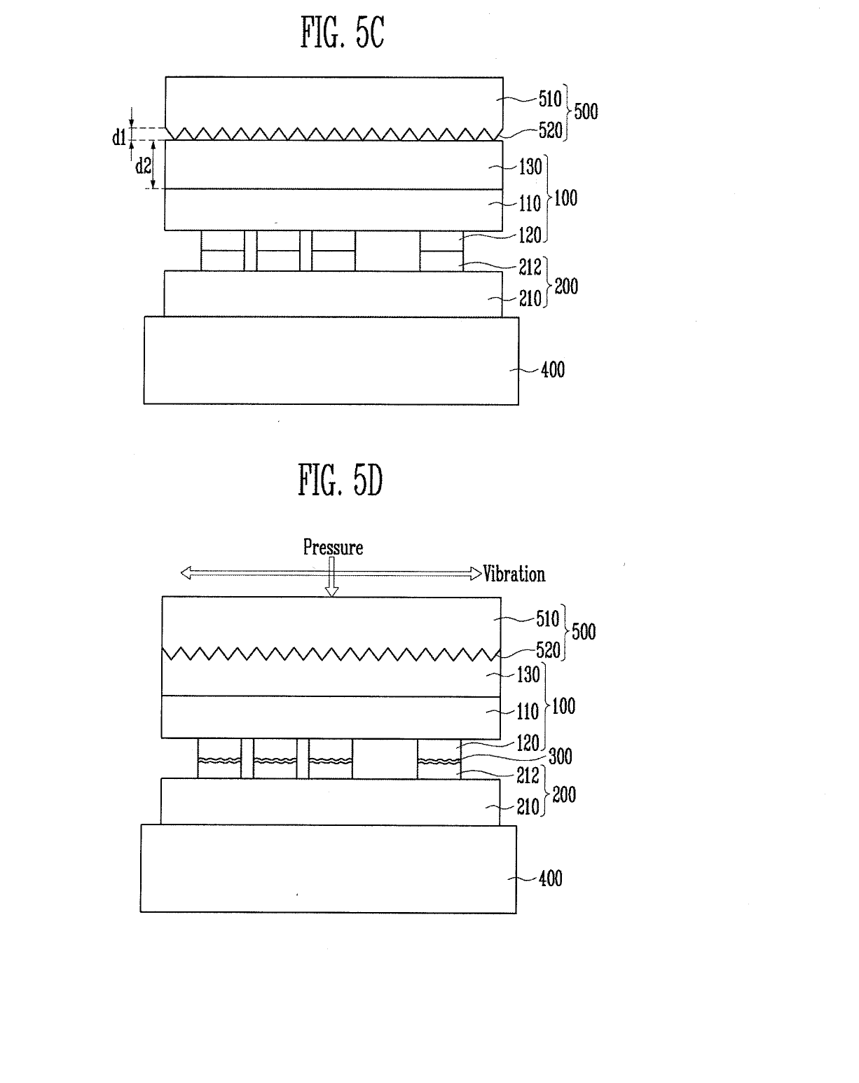

FIG. 2 is a perspective view illustrating an electronic device according to an embodiment of the present disclosure. FIG. 3 is a sectional view schematically illustrating an example of a cross section taken along the line I-I′ of FIG. 2. FIG. 4 is a sectional view schematically illustrating another example of a cross section taken along the line I-I′ of FIG. 2. According to an embodiment, although FIGS. 2 to 4 illustrate a display device as an example of the electronic device, the electronic device according to the present disclosure is not limited to only a display device. In FIGS. 2 to 4, the same reference numerals will be used to indicate the same or similar components (e.g., the semiconductor chip) as those of FIGS. 1A and 1B, and detailed descriptions thereof will be omitted.

Referring to FIGS. 2 to 4, an electronic device according to an embodiment of the present disclosure may be a display device, as an example. The electronic device may include a display panel 200 and a semiconductor chip 100 mounted thereon.

According to an embodiment, the display panel 200 may include a first substrate 210 and a second substrate 220, which overlap each other in at least an active area AA, and a plurality of connecting pads 212, which are provided in a non-active area NA of the first substrate 210. The active area AA may be an area in which at least pixels are located, referring to an area in which an image is displayed. The non-active area NA may refer to a remaining area of the display device 200 that is other than the active area AA, and that includes, for example, a wiring area, a pad area, and/or various kinds of dummy areas, etc. According to an embodiment, although the display panel 200 may be any one of an organic electroluminescent display panel, a liquid crystal display panel, and a plasma display panel, the kind of the display panel 200 is not limited to the above.

According to an embodiment, at least one of the first substrate 210 and the second substrate 220 may be a glass substrate or a plastic substrate. For example, the first substrate 210 and/or the second substrate 220 may be a flexible substrate including at least one of polyethersulfone (PES), polyacrylate, polyetherimide (PEI), polyethylene naphthalate (PEN), polyethylene terephthalate (PET), polyphenylene sulfide (PPS), polyarylate (PAR), polyimide (PI), polycarbonate (PC), cellulose triacetate (TAC), and cellulose acetate propionate (CAP). The first substrate 210 and/or the second substrate 220 may be a rigid substrate including either glass or reinforced glass. Although the first substrate 210 and/or the second substrate 220 may be a substrate made of transparent material, the present disclosure is not limited thereto.

According to another embodiment, at least one of the first substrate 210 and the second substrate 220 may be embodied by an insulating layer including at least one inorganic layer and/or at least one organic layer. For instance, the second substrate 220 may be a thin film encapsulation (TFE) layer including at least one inorganic layer and/or at least one organic layer.

According to an embodiment, the connecting pads 212 may be made of conductive material, and may be connected to various signal lines and/or power lines. For instance, the connecting pads 212 may include at least one kind of metal (e.g., a first metal). Although examples of the metal that forms the connecting pads 212 may include copper (Cu), silver (Ag), gold (Au), platinum (Pt), palladium (Pd), nickel (Ni), tin (Sn), aluminum (Al), cobalt (Co), rhodium (Rh), iridium (Ir), iron (Fe), ruthenium (Ru), osmium (Os), manganese (Mn), molybdenum (Mo), tungsten (W), niobium (Nb), tantalum (Ta), titanium (Ti), bismuth (Bi), antimony (Sb), lead (Pb), etc., the present embodiment is not limited thereto. The connecting pads 212 may be made of a single metal or an alloy. In addition, other material, as well as the above-described metals, may be used to form the connecting pads 212, so long as the material can provide conductivity to the connecting pads 212. The connecting pads 212 may have a single-layer or multi-layer structure, and the structure thereof is not limited to a special structure. The connecting pads 212 may transmit various powers and/or signals, which may be used to drive the display panel 200, between the display panel 200 and the semiconductor chip 100.

According to an embodiment, the semiconductor chip 100 may be mounted in the non-active area NA on the first substrate 210. The semiconductor chip 100 may include a driving circuit for driving the display panel 200. For instance, a scan driving circuit and/or a data driving circuit may be integrated in the semiconductor chip 100.

In an embodiment, the semiconductor chip 100 shown in FIGS. 2 to 4 may be the semiconductor chip 100 according to the embodiment described with reference to FIGS. 1A and 1B. That is, the semiconductor chip 100 may include a base substrate 110, a plurality of connecting terminals 120, which are located on a first surface of the base substrate 110, and a non-adhesive polymer layer 130, which is located on a second surface of the base substrate 110. According to an embodiment, the first surface and the second surface may face each other, and the first surface may be located facing the display panel 200, particularly, the non-active area NA of the first substrate 210.

According to an embodiment, the connecting terminals 120 may be located facing the connecting pads 212 on the first substrate 210, and may be electrically connected to the connecting pads 212. The connecting terminals 120 may include at least a second metal. According to an embodiment, the second metal may be the same as, or different from, the first metal. In other words, the first metal and the second metal may be the same kind of metal, or may be different kinds of metals. A protective layer may be located in at least one area or a peripheral area of the connecting terminals 120 and/or the connecting pads 212.

In an embodiment of the present disclosure, a conductive joining layer 300 may be provided between each of the connecting pads 212 and the associated connecting terminals 120. The conductive joining layer 300 may include a mixture of the first metal included in the connecting pads 212 and the second metal included in the connecting terminals 120. For example, the conductive joining layer 300 may be a solid joining layer that is formed in such a way that, when the semiconductor chip 100 is connected (or bonded) to the display panel 200, the surfaces of the connecting terminals 120 and the connecting pads 212 are melted by heat, which may be generated by friction therebetween, and then are solidified. The conductive joining layer 300 may include a diffusion layer in which the first metal and the second metal are mixed. Each conductive joining layer 300 is interposed between the associated connecting pad 212 and the associated connecting terminal 120, which correspond to each other, and thus electrically connects them to each other. In other words, the connecting pads 212 and the semiconductor chip 100 may be electrically connected to each other by the conductive joining layer 300.

According to an embodiment, although the connecting pads 212 and/or the connecting terminals 120 may have a fine width and/or pitch (e.g., ranging from 5 μm to 20 μm), the connecting pads 212 and connecting terminals 120 are not so limited. According to an embodiment, the connecting pads 212 and the connecting terminals 120 are directly joined with each other without using an ACF or the like. Therefore, even when the connecting pads 212 and/or the connecting terminals 120 have a fine width and/or pitch, a stable connecting (or joining) structure may be provided therebetween.

The non-adhesive polymer layer 130 may be located on the surface of the semiconductor chip 100 (e.g., on the uppermost layer of the second surface of the semiconductor chip 100). Although the non-adhesive polymer layer 130 may be softer than the base substrate 110, it is not limited to this.

According to an embodiment, the non-adhesive polymer layer 130 may include at least one material that is used for manufacturing an electronic device (e.g., the display panel 200) to be coupled with the semiconductor chip 100. For instance, the polymer layer 130 may include at least one material that constitutes a sealant for sealing the active area AA of the display panel 200, or a sealing agent located on the perimeter of the display panel 200 to prevent a crack of the display panel 200. Alternatively, the polymer layer 130 may be made of the same material as that of the sealant or the sealing agent. For example, the polymer layer 130 may include silicon sealant or photocurable resin. However, the present disclosure is not limited to this, and the material constituting the polymer layer 130 may be changed in various ways. For example, when the display panel 200 is formed of flexible thin film material, the polymer layer 130 may include at least one of soft materials constituting the first substrate 210 and/or the second substrate 220. For instance, when the first substrate 210 and/or the second substrate 220 is a flexible thin-film substrate that is formed of PDMS, polyurethane, or the like, the polymer layer 130 may include at least one of PDMS and polyurethane. As such, when the polymer layer 130 is directly formed on the base substrate 110 using material that is used to form the display panel 200, there are advantages in terms of the production cost or the efficiency of the process. The polymer layer 130 may be prevented from being removed from the original position thereof during the joining process of forming the conductive joining layer 300, whereby the grip force between the semiconductor chip 100 and the vibration device may be enhanced. When the polymer layer 130 is formed of stability-verified material used to form the display panel 200, the stability of an electronic device including the semiconductor chip 100 may be secured.

The soft polymer layer 130 may have predetermined elasticity and restoring force. Depending on the degree of elasticity and restoring force of the polymer layer 130, after the joining process has been completed, the surface of the polymer layer 130 may be substantially planar, as shown in FIG. 3, or may have a plurality of recesses 132, as shown in FIG. 4. According to an embodiment, the polymer layer 130 may have a thickness (e.g., ranging from 30 μm to 40 μm) that is greater than the height of protrusions that are embedded into the polymer layer 130 during the joining process. Therefore, although the protrusions of the vibration device are embedded into the polymer layer 130, the base substrate 110, or a circuit layer on the base substrate 110, is prevented from being damaged. In addition, although the recesses 132 remain in the surface of the polymer layer 130, they may not affect the performance of the semiconductor chip 100.

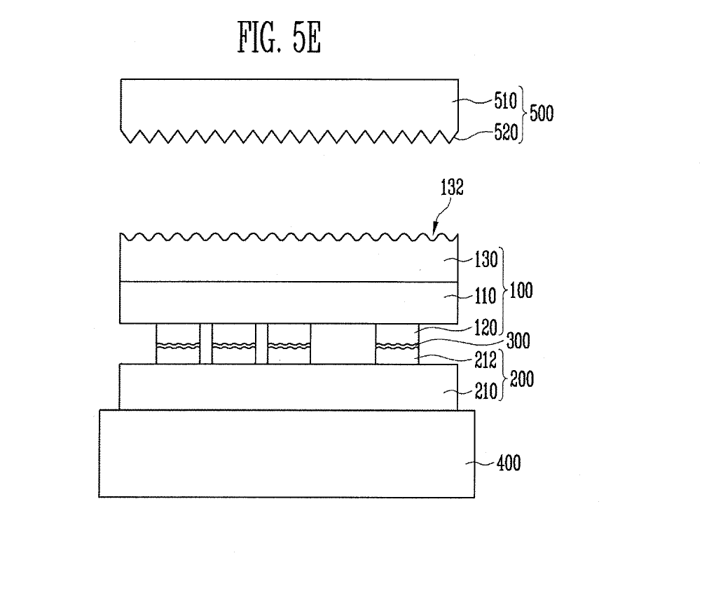

FIGS. 5A to 5E are sectional views illustrating a method of connecting a semiconductor chip to an electronic device (e.g., a display panel) according to an embodiment of the present disclosure. A semiconductor chip and a display panel that are shown in FIGS. 5A to 5E may be the semiconductor chip and the display panel according to one of the embodiments described with reference to FIGS. 1A to 4. Therefore, in FIGS. 5A to 5E, the same reference numerals will be used to indicate the same or similar components as those of FIGS. 1A to 4, and repeated detailed descriptions thereof will be omitted.

Hereinafter, a method of connecting the semiconductor chip 100 according to an embodiment of the present disclosure will be successively explained with reference to FIGS. 5A to 5E.

First, as shown in FIG. 5A, a display panel 200 including a first substrate 210, which includes a plurality of connecting pads 212 on at least one surface thereof, is prepared. Thereafter, the display panel 200 including the first substrate 210 is placed on a support 400. For example, the display panel 200 including the connecting pads 212 may be transferred above the support 400, and may then be placed on the support 400 such that the connecting pads 212 are oriented upward.

Subsequently, a semiconductor chip 100 including connecting terminals 120 and a non-adhesive polymer layer 130, which are respectively located at opposite sides, is prepared. Thereafter, as shown in FIG. 5B, the semiconductor chip 100 is aligned on the first substrate 210 such that respective ones of the connecting pads 212 and the connecting terminals 120 face each other.

As shown in FIG. 5C, a vibration device 500 including a vibration head 510 provided with a plurality of protrusions 520 is thereafter located on the semiconductor chip 100. According to an embodiment, the vibration device 500 may be a device capable of applying vibration having a frequency in the ultrasonic range.

The protrusions 520 may be located on a side of the vibration head 510 that faces the semiconductor chip 100. For example, the protrusions 520 may be integrally formed with the vibration head 510. For instance, the vibration head 510 and the protrusions 520 may be integrally formed of a light alloy.

Although the size of the protrusions 520 has been exaggerated in FIG. 5C for the sake of clear illustration, each protrusion 520 may have a fine size according to an embodiment. For example, the protrusions 520 may have a height d1 of approximately 20 μm. The polymer layer 130 located on the surface (e.g., the uppermost layer) of the semiconductor chip 100 may be made of material that is softer than that of the protrusions 520, and may have a thickness d2 that is greater than the height d1 of the protrusions 520 so that the protrusions 520 can be easily received in the polymer layer 130. For example, the thickness d2 of the polymer layer 130 may be greater than the height d1 of the protrusions 520 by 10 μm or more. Furthermore, the thickness d2 of the polymer layer 130 may be within a range in which the polymer layer 130 can be easily formed on the base substrate 110. For instance, the thickness d2 of the polymer layer 130 may range from 30 μm to 40 μm.

Although, in the present embodiment, the step of transferring and aligning the semiconductor chip 100 and the step of disposing the vibration device 500 have been illustrated as being separate steps, the present disclosure is not limited to this. For example, in another embodiment, the vibration device 500 may be integrally embodied with a device for transferring the semiconductor chip 100.

Subsequently, as shown in FIG. 5D, the vibration device 500 is operated, and the vibration head 510 is moved downward such that the protrusions 520 are embedded into the polymer layer 130. Thereafter, the vibration device 500 presses the semiconductor chip 100 (e.g., at a predetermined pressure). Furthermore, while pressing the semiconductor chip 100, the vibration device 500 vibrates the semiconductor chip 100 (e.g., at a predetermined frequency), thereby joining the connecting pads 212 with the connecting terminals 120.

For instance, while the semiconductor chip 100 is pressed by the vibration head 510, vibration having a frequency in the ultrasonic range may be applied to the semiconductor chip 100 in a horizontal direction that is perpendicular to a direction in which a load is applied to the semiconductor chip 100. Thereby, the connecting pads 212 and the connecting terminals 120 may be rapidly rubbed together. As a result, friction is generated between the connecting pads 212 and the connecting terminals 120, and the surfaces of the connecting pads 212 and the connecting terminals 120 are melted by the friction energy. When the surfaces of the connecting pads 212 and the connecting terminals 120 are melted, a diffusion layer is formed between the connecting pads 212 and the connecting terminals 120, and the first metal included in the connecting pads 212 and the second metal included in the connecting terminals 120 are mixed to each other. Thereby, a conductive joining layer 300 is formed. That is, a mixture of the first metal and the second metal may be included in the conductive joining layer 300.

In an embodiment of the present disclosure, a direct metal-to-metal joining process is performed in a state in which the protrusions 520 are brought into close contact with the polymer layer 130 by embedding the protrusions 520 into the polymer layer 130. Therefore, during the joining process, the vibration head 510 integrally vibrates with the semiconductor chip 100. In addition, even if the base substrate 110 of the semiconductor chip 100 and/or the first substrate 210 of the electronic device (e.g., the display panel 200), which is coupled with the semiconductor chip 100, has flexibility, the semiconductor chip 100 may be prevented from slipping on the first substrate 210 because the semiconductor chip 100 comes into close contact with the vibration head 510. Therefore, according to an embodiment of the present disclosure, the connecting terminals 120 of the semiconductor chip 100 may be stably and directly joined with the connecting pads 212 of the electronic device.

In detail, according to an embodiment of the present disclosure, because the polymer layer 130 is formed on the surface of the semiconductor chip 100, a displacement loss that may be caused during the joining process may be reduced, and vibration energy that is generated by the vibration device 500 may be effectively transmitted to the semiconductor chip 100. Consequently, friction energy between the connecting terminals 120 of the semiconductor chip 100 and the connecting pads 212 of the electronic device may be increased. As a result, the connecting terminals 120 and the connecting pads 212 are melted without using a high pressure process, which requires a high pressure under which the semiconductor chip 100 or the first substrate 210 coupled thereto may be damaged. Thereby, a diffusion layer may be easily formed between the connecting terminals 120 and the connecting pads 212. Consequently, a high-quality conductive joining layer 300 may be formed between the connecting terminals 120 and the connecting pads 212. According to an embodiment of the present disclosure, for example, even when the semiconductor chip 100 and/or the display panel 200 have flexibility, the semiconductor chip 100 may be stably connected (or bonded) to the display panel 200.

When the conductive joining layer 300 formed between the connecting pads 212 and the connecting terminals 120 is sufficient to electrically couple the connecting pads 212 with the connecting terminals 120, the application of the pressure and the vibration is stopped. Thereafter, as shown in FIG. 5E, the vibration device 500 is removed from the semiconductor chip 100. In an embodiment of the present disclosure, because the polymer layer 130 is formed of non-adhesive insulating material, the vibration device 500 may be removed from the semiconductor chip 100. Consequently, the efficiency of the process may be increased.

After the semiconductor chip 100 and the vibration device 500 are separated from each other, recesses 132 may be at least temporarily formed on the surface of the polymer layer 130 by the embedment of the protrusions 520. However, depending on the material of the polymer layer 130, the recesses 132 may remain in the surface of the polymer layer 130, or, as time passes, the surface of the polymer layer 130 may be substantially planarized by the restoring force of the polymer layer 130.

The conductive joining layer 300 formed between the connecting pads 212 and the connecting terminals 120 is hardened to a solid form after the vibration and the pressure have been removed. As a result, the solid-phase conductive joining layer 300 is formed between the connecting pads 212 and the connecting terminals 120. According to an embodiment, the conductive joining layer 300 may be formed of a diffusion layer in which the first metal constituting the connecting pads 212 and the second metal constituting the connecting terminals 120 are mixed.

As described above, in an embodiment of the present disclosure, the semiconductor chip 100 is mounted on the first substrate 210 in such a way that the connecting pads 212 are directly joined with the connecting terminals 120 by friction generated between the connecting pads 212 and the connecting terminals 120 using ultrasonic waves. According to an embodiment of the present disclosure, the semiconductor chip 100 may be stably coupled with (or connected to) the connecting pads 212 located on the first substrate 210 without using an ACF or the like.

Particularly, in an embodiment of the present disclosure, the soft non-adhesive polymer layer 130 is formed on the surface of the semiconductor chip 100 to enhance the grip force between the semiconductor chip 100 and the vibration device 500. Consequently, even when the protrusion-type vibration device 500 having excellent holding power is used to perform the joining process, the semiconductor chip 100 may be prevented from being damaged, and the holding power of the vibration device 500 may be further enhanced. Thereby, not only may the joining process between the same kind or different kinds of metals be stably performed, but the high-quality joining layer 300 may also be formed. According to an embodiment of the present disclosure, low-resistance characteristics may be ensured by a direct joining structure between the connecting terminals 120 and the connecting pads 212.

Example embodiments have been disclosed herein, and although specific terms are employed, they are used in, and are to be interpreted in, a generic and descriptive sense only, and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth by the following claims and their functional equivalents.

What is claimed is:

1. An electronic device comprising:
a substrate provided with a plurality of connecting pads comprising a first metal;
a semiconductor chip on an area of the substrate, facing the connecting pads, and comprising:
a base substrate comprising a first surface facing the substrate, and a second surface opposite the first surface;
a plurality of connecting terminals on the first surface, facing the connecting pads, and comprising a second metal; and
a non-adhesive polymer layer on the second surface; and
a conductive joining layer electrically connecting, and interposed between, respective ones of the connecting pads to the connecting terminals, and comprising a diffusion layer in which the first metal and the second metal are mixed.

2. The electronic device of claim 1, wherein the polymer layer comprises at least one of silicon sealant, photocurable resin, polydimethylsiloxane and polyurethane.

3. The electronic device of claim 1, wherein the polymer layer comprises insulating material that is softer than material of the base substrate.

4. The electronic device of claim 1 provided with a display panel comprising the substrate.

5. The electronic device of claim 4, wherein the polymer layer comprises at least one of a material that forms a sealant sealing a display area of the display panel, and a material that forms a sealing agent located on a perimeter of the display panel.

6. The electronic device of claim 1, wherein the substrate comprises a flexible thin-film substrate.

7. The electronic device of claim 6, wherein the polymer layer comprises a material of the substrate.

8. The electronic device of claim 1, wherein the polymer layer has a thickness ranging from about 30 μm to about 40 μm.

9. The electronic device of claim 1, wherein the first metal and the second metal comprise an identical kind of metal or different kinds of metals.

10. A semiconductor chip comprising:
a base substrate;
a plurality of connecting terminals on a first surface of the base substrate; and
a non-adhesive polymer layer located on a second surface of the base substrate opposite the first surface.

11. The semiconductor chip according to claim 10, wherein the polymer layer comprises at least one of silicon sealant, photocurable resin, polydimethylsiloxane and polyurethane.

12. The semiconductor chip according to claim 10, wherein the polymer layer has a thickness ranging from about 30 μm to about 40 μm.

13. A method of connecting a semiconductor chip to an electronic device, the method comprising:
preparing a substrate comprising a plurality of connecting pads;
preparing a semiconductor chip comprising a plurality of connecting terminals, and a non-adhesive polymer layer, on respective surfaces facing away from each other;
aligning the semiconductor chip on the substrate such that the connecting pads and the connecting terminals face each other;
disposing a vibration device on the semiconductor chip, the vibration device comprising a plurality of protrusions;
joining the connecting pads with the connecting terminals by:
pressing the semiconductor chip using the vibration device such that the protrusions are embedded into the polymer layer; and
vibrating the semiconductor chip; and
removing the vibration device from the semiconductor chip.

14. The method according to claim 13, wherein the joining of the connecting pads with the connecting terminals comprises forming a conductive joining layer between the connecting pads and the connecting terminals, the conductive joining layer comprising a mixture of a first metal of the connecting pads and a second metal of the connecting terminals.

15. The method according to claim 14, wherein the first metal and the second metal comprise an identical kind of metal or different kinds of metals.

16. The method according to claim 13, wherein the joining of the connecting pads with the connecting terminals comprises applying vibration having a frequency in an ultrasonic range to the semiconductor chip to vibrate the semiconductor chip in a horizontal direction that is perpendicular to a direction in which a load is applied to the semiconductor chip.

17. The method according to claim 13, wherein the polymer layer has a thickness that is greater than a height of the protrusions.
